(19) United States
(12) Patent Application Publication
(10) Pub. No.: US 2026/0082942 A1
(43) Pub. Date: Mar. 19, 2026

(54) Transistor Chip Package with Internal Clip Interconnect

(71) Applicant: Infineon Technologies Austria AG, Villach (AT)

(72) Inventors: Guey Yong Chee, Batu Berendam (MY); Fitri Rafzanjani Mat, Seremban (MY); Chii Shang Hong, Bukit Katil (MY); Joo Teng Teoh, Melaka (MY); Ke Yan Tean, Paya Rumput (MY); Thai Kee Gan, Melaka Tengah (MY)

(21) Appl. No.: 19/311,138

(22) Filed: Aug. 27, 2025

(30) Foreign Application Priority Data
Sep. 19, 2024 (DE) 102024126905.7

(51) Int. Cl. H10W 70/40; H10W 72/60; H10W 90/00

(52) U.S. Cl. CPC H10W 70/466; H10W 72/621; H10W 72/647; H10W 90/766

(57) ABSTRACT

A semiconductor package includes a transistor chip having first and second opposite facing sides. The semiconductor transistor chip includes a first load electrode and a second load electrode on the first side. The package includes a carrier facing the second side of the chip, a first terminal post laterally beside the transistor chip and a second terminal post laterally beside the transistor chip. The second terminal post is a part of the carrier or physically connects to the carrier. A first clip connects the first load electrode to the first terminal post. A second clip connects the second load electrode to the second terminal post. An upper surface of the first terminal post and an upper surface of the second terminal post are arranged at different levels of height. The first clip and the second clip are of same shape.

### TECHNICAL FIELD

This disclosure relates generally to the technique of semiconductor packaging, and in particular to a transistor chip package using clips for an internal package interconnect.

### BACKGROUND

Semiconductor packages are widely used as electronic switches in a variety of electronic circuits. Higher efficiency, increased power density, lower switching losses, faster switching times, lower device resistances and device parasitics and lower cost are among the key goals for next generation semiconductor package design.

Conventional approaches to reduce device resistances and device parasitics and to improve thermal behavior are to use clips for connecting the load electrodes of a semiconductor transistor chip to the respective terminals of the semiconductor package. Clip attachment, which is typically carried out by clip attachment machines, significantly contributes to the overall packaging cost.

### SUMMARY

According to a first aspect of the disclosure, a semiconductor package comprises a transistor chip having a first side and a second side opposite the first side. The transistor chip comprises a first load electrode and a second load electrode on the first side. The package comprises a carrier facing the second side of the transistor chip, a first terminal post arranged laterally beside the transistor chip and a second terminal post arranged laterally beside the transistor chip on an opposite side of the transistor chip. The second terminal post is a part of the carrier or physically connects to the carrier. A first clip connects the first load electrode to the first terminal post. A second clip connects the second load electrode to the second terminal post. An upper surface of the first terminal post and an upper surface of the second terminal post are arranged at different levels of height measured from an upper surface of the carrier. The first clip and the second clip are of same shape.

According to a second aspect of the disclosure, a semiconductor package comprises a transistor chip having a first side and a second side opposite the first side. The transistor chip comprises a first load electrode and a second load electrode on the first side. The package comprises a carrier facing the second side of the transistor chip, a first terminal post arranged laterally beside the transistor chip and a second terminal post arranged laterally beside the transistor chip on an opposite side of the transistor chip. The second terminal post is a part of the carrier or physically connects to the carrier. A first clip connects the first load electrode to the first terminal post. A second clip connects the second load electrode to the second terminal post. An upper surface of the first terminal post and an upper surface of the second terminal post are arranged at different levels of height measured from an upper surface of the carrier. The first clip comprises a vertical clip portion extending in a vertical direction and a horizontal clip portion extending in a horizontal direction, the horizontal clip portion having a first horizontal section and a second horizontal section, the first horizontal section and the second horizontal section are connected by a vertically stepped section.

According to another aspect of the disclosure, a method of manufacturing the semiconductor package according to the first aspect comprises providing the first terminal post and providing the second terminal post. The method further comprises placing the transistor chip on the carrier. The first clip is placed to connect between the first load electrode and the first terminal post. The second clip is placed to connect between the second load electrode and the second terminal post.

### BRIEF DESCRIPTION OF THE DRAWINGS

In the drawings, like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIG. 1 is a schematic cross-sectional view of an example of a semiconductor package including a transistor chip and first and second clips of an internal interconnect according to the first aspect.

FIG. 2 is a schematic cross-sectional view of an example of a semiconductor package including a transistor chip and first and second clips of an internal interconnect according to the second aspect.

FIG. 3 is a top view of an example of a semiconductor package such as, e.g., shown in FIG. 1 or 2.

FIG. 4 is a schematic top view on a clip attach frame according to the first aspect.

FIG. 5 is a schematic top view on a clip attach frame according to the second aspect.

FIG. 6A is schematic cross-sectional view of a conventional transistor chip package containing two clips of different shape.

FIG. 6B is schematic cross-sectional view of the conventional transistor chip package of FIG. 6A during manufacturing, illustrating insufficient free length in a clip frame for clip bending.

FIG. 7 is a perspective top view of an example of a second clip according to the disclosure.

FIG. 8 is a flowchart for showing exemplary stages of manufacturing a transistor chip package according to the first aspect.

FIG. 9 is a flowchart for showing exemplary stages of manufacturing a transistor chip package according to the second aspect.

### DETAILED DESCRIPTION

It is to be understood that the features of the various exemplary embodiments and examples described herein may be combined with each other unless specifically noted otherwise.

As used in this specification, the terms “electrically connected” or “electrically coupled” or similar terms are not meant to mean that the elements are directly contacted together; intervening elements may be provided between the “electrically connected” or “electrically coupled” elements, respectively. However, in accordance with the disclosure, the above-mentioned and similar terms may, optionally, also have the specific meaning that the elements are directly contacted together, i.e. that no intervening elements are provided between the “electrically connected” or “electrically coupled” elements, respectively.

Further, the words “over” or “beneath” with regard to a part, element or material layer formed or located or arranged “over” or “beneath” a surface may be used herein to mean that the part, element or material layer be located (e.g. placed, formed, arranged, deposited, etc.) “directly on” or “directly under”, e.g. in direct contact with, the implied surface. The word “over” or “beneath” used with regard to a part, element or material layer formed or located or arranged “over” or “beneath” a surface may, however, either be used herein to mean that the part, element or material layer be located (e.g. placed, formed, arranged, deposited, etc.) “indirectly on” or “indirectly under” the implied surface, with one or more additional parts, elements or layers being arranged between the implied surface and the part, element or material layer.

FIG. 1 illustrates a cross-sectional view of an example of a semiconductor package 100. The semiconductor package 100 includes a carrier 110 and a transistor chip (die) 120 mounted on the carrier 110.

More specifically, the transistor chip 120 has a first side 120A and a second side 120B opposite the first side 120A. The second side 120B of the transistor chip 120 faces the carrier 110. For example, the second side 120B of the transistor chip 120 may be attached to the carrier 110 by bonding material 130, e.g., a solder material, a sinter paste or an electrically conducting glue.

The carrier 110 may, e.g., be a metallic carrier such as, e.g., a part of a leadframe (die pad of the leadframe, for example). The leadframe may be a so-called downset leadframe (leadframe having a downset portion which includes the carrier 110). In a downset leadframe, the first terminal post 140_1 (see below) is higher than the carrier 110.

In other examples, the carrier 110 may, e.g., comprise or be a PCB (printed circuit board) or a ceramic-based carrier such as, e.g., a DCB (direct copper bonding) carrier or an AWB substrate.

The transistor chip 120 includes a first load electrode 122_1 and a second load electrode 122_2. The first load electrode 122_1 and the second load electrode 122_2 are arranged on the first side 120A of the transistor chip 120.

For example, the first load electrode 122_1 may be a drain (D) electrode of the transistor chip 120 and the second load electrode 122_2 may be a source (S) electrode of the transistor chip 120.

The transistor chip 120 may be configured as a power semiconductor chip. Power chips are suitable, in particular, for switching high currents and/or medium or high voltages (e.g., more than 50 V or 100 V or 200 V or 300 V blocking voltage). In particular, exemplary semiconductor packages as disclosed herein may operate in the medium voltage (MV) range, in which the blocking voltage is equal to or greater than or less than 200 V or 150 V or 100 V or 50 V.

The transistor chip 120 may be of different types. Examples described herein are, in particular, directed to HEMT (high electron mobility transistor) devices. More specifically, the transistor chip 120 referred to herein may, e.g., be a III-V compound semiconductor chip having, e.g., a high band gap. The transistor chip 120 may, e.g., be a GaN chip. In this case, the GaN chip 120 may, e.g., be a lateral GaN-on-substrate device such as a GaN-on-Si device or a GaN-on-SiC device or a GaN-on-sapphire device, for example.

In general, the transistor chip 120 may, e.g., be a lateral semiconductor device having load electrodes 122_1, 122_2 only at the first side 120A of the transistor chip 120. In lateral semiconductor devices, the load current is flowing mainly in a lateral (horizontal) direction between the load electrodes 122_1, 122_2.

The semiconductor package 100 further includes a first terminal post 140_1 arranged laterally beside the transistor chip 120 and a second terminal post 140_2 arranged laterally beside the transistor chip 120 on an opposite side of the transistor chip 120.

The semiconductor package 100 further includes a first clip 160_1 and a second clip 160_2. The first clip 160_1 connects the first load electrode 122_1 to the first terminal post 140_1. The second clip 160_2 connects the second load electrode 122_2 to the second terminal post 140_2. The first clip 160_1 and the second clip 160_2 may be made, e.g., of copper or aluminum or a copper-based or aluminum-based alloy, for example.

The first clip 160_1 and the second clip 160_2 are configured as load current clips. In the example shown, the first clip 160_1 is, e.g., a drain clip and the second clip 160_2 is, e.g., a source clip.

An upper surface 140_1A of the first terminal post 140_1 and an upper surface 140_2A of the second terminal post 140_2 are arranged at different levels of height measured from an upper surface 110A of the carrier 110. For example, the height of the upper surface 140_1A of the first terminal post 140_1 is H1. The height of the upper surface 140_2A of the second terminal post 140_2 over the upper surface 110A of the carrier 110 is, for example, zero (if the second terminal post 140_2 is, e.g., formed by an area on the upper surface 110A of the carrier 110).

In other examples (not shown), the upper surface 140_2A of the second terminal post 140_2 (to which the second clip 160_2 is connected) may, e.g., be elevated from the upper surface 110A of the carrier 110 which serves as a mounting platform for the transistor chip 120. For example, the carrier 110 may be provided with a protrusion or pedestal having an upper surface 140_2A arranged at a height (not shown) over the upper surface 110A of the carrier 110. In general, the second terminal post 140_2 is a part of the carrier 110 or physically connects to the carrier 110.

In the following, the distance between the upper surface 140_1A of the first terminal post 140_1 and the upper surface of the transistor chip 120 at the first side 120A thereof is referred to as SOH (standoff height) of the first clip 160_1. In other words, SOH is the free height bridged by the first clip 160_1. Typically, in particular in cases in which a lower surface 110B of the carrier 110 remains exposed at the semiconductor package 100, the SOH of the first clip 160_1 may need to be rather high. For example, the SOH may, e.g., be equal to or greater than or less than 250 μm, 300 μm, 350 μm, 400 μm, 450 μm, or 500 μm. These rather large values for the SOH may, e.g., be due to a minimum height H1 which is required in some examples of packaging transistor chips 120.

The first load electrode 122_1 and the second load electrode 122_2 of the transistor chip 120 are laterally spaced apart by a gap of width W. Typically, W may, e.g., be equal to or less than or greater than 250 μm, 300 μm or 350 μm.

For example, W<SOH. In this case, the bent part (i.e., the vertical section 160_1V, 160_2V) of the clips 160_1, 160_2 is longer than the distance between the electrodes 122_1, 122_2.

The first clip 160_1 and the second clip 160_2 may each include a vertical clip portion 160_1V and 160_2V, respectively, and a horizontal clip portion 160_1H and 160_2H, respectively. The horizontal clip portion 160_1H of the first clip 160_1 may be attached to the first terminal post 140_1 (e.g., to the upper surface 140_1A thereof). The vertical clip portion 160_1V of the first clip 160_1 may be attached to the first load electrode 122_1. Similarly, the horizontal clip portion 160_2H of the second clip 160_2 may be attached to the second load electrode 122_2 and the vertical clip portion 160_2V of the second clip 160_2 may, e.g., be attached to the second terminal post 140_2 (e.g., to the upper surface 140_2A thereof).

For each clip 160_1, 160_2, the vertical clip portion 160_1V, 160_2V may be one end of the clip 160_1, 160_2 and the horizontal clip portion 160_1H, 160_2H may be the other end of the clip 160_1, 160_2. The vertical clip portion 160_1V, 160_2V may connect to the horizontal clip portion 160_1H, 160_2H via a clip bending having, e.g., a bending angle of about 90°. For example, each clip 160_1, 160_2 may have only one clip bending, i.e. each clip 160_1, 160_2 may comprise or be composed of the vertical clip portion 160_1V, 160_2V, the clip bending and the horizontal clip portion 160_1H, 160_2H, for example.

The vertical clip portions 160_1V and 160_2V are clip portions which need to be bent down during manufacturing the clips 160_1 and 160_2, respectively. The length of the bent down vertical clip portions 160_1V and 160_2V define a free height H of the first and second clips 160_1, 160_2.

According to the first aspect of the disclosure, the first clip 160_1 and the second clip 160_2 are of the same shape. “Same shape” may actually mean the same shape in 3D dimensions, i.e. identical shape. This also means that only one kind of clip has to be used for the internal interconnect of the semiconductor package 100.

In other words, a universal clip 160_1, 160_2 may be used for contacting the load electrodes 122_1, 122_2 (e.g., drain and source) of the transistor chip 120. The provision of a universal clip reduces the cost of clips 160_1, 160_2, since no two different clips as conventionally are needed, i.e. one drain clip and one source clip. Purchasing two different clips is more expensive than purchasing double volume of same clip.

Clip attachment is typically carried out by pick-and-place operations. Because of the universal clips 160_1, 160_2, pick-and-place processes do not need to consider to pick up different clips connecting source or drain, which saves operation space and/or improves the UPH (units per hour) manufacturing rate.

In particular, the first clip 160_1 and the second clip 160_2 (which are of identical shape according to the first aspect of the disclosure) have necessarily the same free height H. In a specific example, SOH=H can be chosen.

Further, the first clip 160_1 and the second clip 160_2 may include a stepped abutment surface AS at an end section of the horizontal clip portion 160_1H, 160_2H. The abutment surface AS may include a higher abutment surface portion AS1 and a lower abutment surface portion AS2.

For example, the higher abutment surface portion AS1 of the first clip 160_1 is placed on the first terminal post 140_1 (e.g., on the upper surface 140_1A thereof) and the lower abutment surface portion AS2 of the second clip 160_2 is placed on the second load electrode 122_2.

The difference in height of the higher abutment surface portion AS1 and the lower abutment surface portion AS2 may be appropriately set to allow the first clip 160_1 and the second clip 160_2 to be of the same shape. In other words, the height of the upper surface at the first side 120A of the transistor chip 120, as measured from the upper surface 110A of the carrier 110 (this may be the height which is to be bridged by the second clip 160_2), and the height of the upper surface 140_1A of the first terminal post 140_1, as measured from the upper surface of the first side 120A of the transistor chip 120 (this may be the height which is to be bridged by the first clip 160_1), may be different by, e.g., an offset OS. This offset OS may be compensated by the stepped abutment surface AS (e.g., the step height, i.e. the height difference between AS1 and AS2, is set to OS). Then, by virtue of the stepped abutment surface AS, this offset OS does not prevent the first clip 160_1 and the second clip 160_2 to be of the same shape.

As illustrated in FIG. 1, the semiconductor package 100 may include an encapsulant 180. For example, a molding process may be carried out to encapsulate the transistor chip 120 mounted on the carrier 110 with a mold material. The molded encapsulant 180 may, e.g., form the package body.

The carrier 110 may remain exposed at the bottom of the encapsulant 180. The first and second clips 160_1, 160_2 may be completely covered by the encapsulant 180, for example.

In some examples, the semiconductor package 100 is a leaded package. The semiconductor package 100 may, e.g., include leads to form a first package terminal 190_1 and/or a second package terminal 190_2. The leads may, e.g., protrude out of a peripheral side of the encapsulant 180.

For example, the leads forming the first package terminal 190_1 (e.g. D) and/or the second package terminal 190_2 (e.g. S) may be formed as gullwing leads as shown in FIGS. 6A, 6B.

In some examples, the semiconductor package 100 may be a partially leaded package (not shown). Such semiconductor package may, e.g., include one or more leads to form the first package terminal 190_1. The second package terminal 190_2 may, e.g., be leadless, i.e. there is no lead protruding out of the (right) peripheral side of the encapsulant 180. For example, such package may, e.g., be a TOLL (TO-Leadless) package or a TOLG (TO-Leaded with gullwing) package, e.g. a BSC (basic dimension) package. In these packages, the second package terminal 190_2 may, e.g., be formed by an exposed lower surface 110B of the carrier 110.

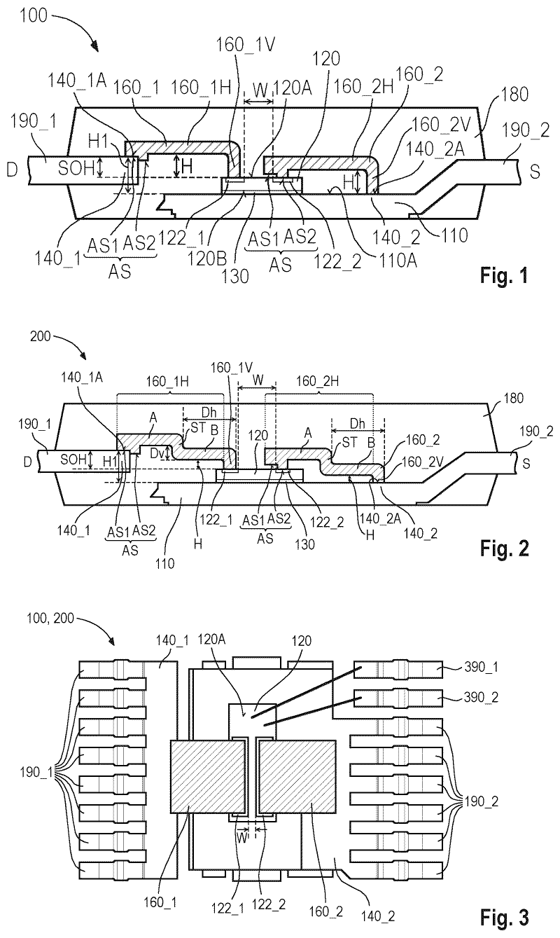

FIG. 2 illustrates an example of a semiconductor package 200 according the second aspect of the disclosure. Semiconductor package 200 is designed largely in accordance with the features described for the semiconductor package 100. Therefore, to avoid reiteration, reference is made to the above description.

The semiconductor package 200 distinguishes from the semiconductor package 100 in clip design. The first clip 160_1 includes a vertical clip portion 160_1V extending in a vertical direction and a horizontal clip portion 160_1H extending in a horizontal direction. The horizontal clip portion 160_1H of the first clip 160_1 has a first section A and a second section B. The first section A and the second section B are connected by a vertically stepped section ST. The vertically stepped section ST allows the horizontal clip portion 160_1H to bridge a difference in height, namely the vertical distance Dv.

The stepped section ST may be used to reduce the free height H of the vertical clip portion 160_1V. For example, compared to the semiconductor package 100 shown in FIG. 1, the free height H of the vertical clip portion 160_1V is reduced by Dv, i.e. H(package 200)=H(package 100)−Dv. In particular, as H(package 100) may be equal to SOH, the free height H of semiconductor package 200 may, e.g., read H=SOH−Dv.

That way it is possible to dimension H to be smaller than the width W of the gap between the first load electrode 122_1 and the second load electrode 122_2. This allows to form the first clip 160_1 and the second clip 160_2 within the same clip frame, as will be described in more detail further below. As a result, the first clip 160_1 and the second clip 160_2 may, e.g., be placed on the transistor chip 120 and the terminal posts 140_1, 140_2 together by a single placement process. This reduces cost of the clip attachment process, since only one clip attachment operation per semiconductor package 200 is required.

In semiconductor package 200, SOH may, e.g., be equal to or greater than or less than 250 μm, 300 μm, 350 μm, 400 μm, 450 μm, or 500 μm (i.e., may adopt the same values as in semiconductor package 100). For example, Dv may, e.g., be equal to or greater than or less than 300 μm, 250 μm, 200 μm, 150 μm, or 100 μm. Similar ranges apply for H, which can, e.g., be equal to or greater than or less than 300 μm, 250 μm, 200 μm, 150 μm, or 100 μm (with, e.g., H<W to allow in-frame clip bending, see for explanation FIG. 6B).

The “lowered” second section B of the horizontal clip portion 160_1H of the first clip 160_1 may have a length which is denoted as horizontal distance Dh. The horizontal distance Dh is the distance between the end of the first clip 160_1 at the vertical clip portion 160_1V (i.e. the end of the first clip 160_1 at the right side in FIG. 2) and the vertically stepped section ST.

In semiconductor package 200, Dh may, e.g., be equal to or greater than 0.5 mm, 0.75 mm, or 1.0 mm. This allows to use an upper flat surface of the second section B to provide enough space for a pickhead (not shown) of a pick-and-place assembly unit used for placing the first clip 160_1 on the transistor chip 120.

More specifically, a pickhead of a pick-and-place assembly unit may be provided with suction areas which require a flat surface area having a minimum size on clips to be handled by the pick-and-place assembly unit. This area may be provided by the upper flat surface of the second section B of the first clip 160_1 (and analogously the second clip 160_2).

The “higher” second section A of the horizontal clip portion 160_1H of the first clip 160_1 may have a length measured between the opposite end (at the left side in FIG. 2) of the first clip 160_1 and the vertically stepped section ST. This length can be equal to, greater than or less than 0.5 mm, 0.75 mm, or 1.0 mm (similar to the length Dh, for example).

According to the second aspect of the disclosure, the first clip 160_1 and the second clip 160_2 may, e.g., be of the same shape, as exemplified by FIG. 2. However, it is also possible that the first clip 160_1 and the second clip 160_2 are of different shape. The first clip 160_1 is shaped to include the stepped section ST, while the second clip 160_2 may, e.g., be shaped as shown in FIG. 1 relating to semiconductor package 100.

FIG. 3 shows a top view of an example of a semiconductor package such as, e.g., semiconductor packages 100, 200 shown in FIGS. 1 and 2, respectively. For illustrative purposes, the encapsulation 180 is omitted.

For example, the first package terminal 190_1 includes a plurality of leads extending from the first terminal post 140_1. The second package terminal 190_2 may also include a plurality of leads extending from the second terminal post 140_2. As mentioned before, the second terminal post 140_2 may be connected to or located on the carrier 110. For example, the second terminal post 140_2 may be formed by an area of the upper surface 110A of the carrier 110 on which the second clip 160_2 is placed.

The first package terminal 190_1 may extend along a majority or the entire length at one side of the semiconductor package 100, 200. The second package terminal 190_2 may also extend along a majority or the entire length at the opposite side of the semiconductor package 100, 200.

The semiconductor package 100, 200 may further include a package terminal 390_1 and/or a package terminal 390_2. The package terminal 390_1 and/or the package terminal 390_2 may be connected, e.g., to a control electrode (e.g. gate) and/or a sense electrode on the first side 120A of the transistor chip 120.

As shown in FIG. 3, the first load electrode 122_1 and/or the second load electrode 122_2 may be formed as parallel stripes extending along the longitudinal dimension of the transistor chip 120. The distance between these stripes is the gap of width W.

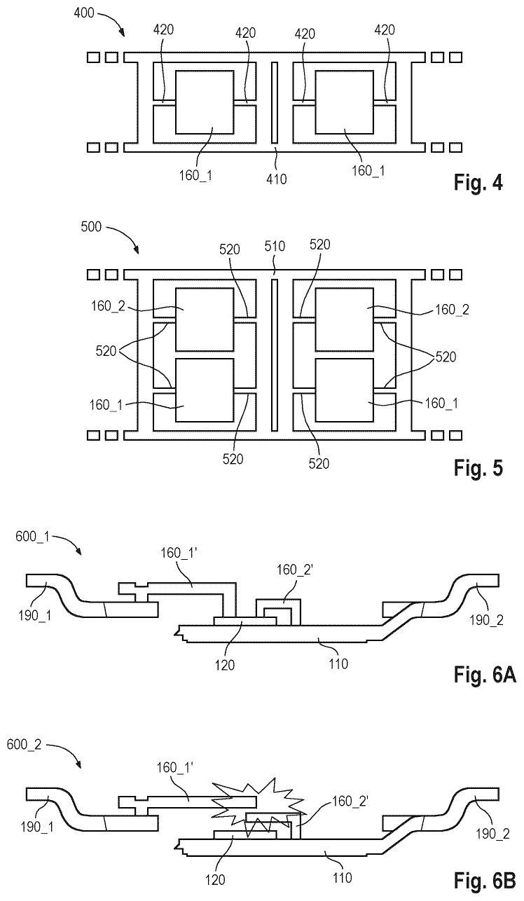

FIG. 4 shows a clip attach frame 400 according to the first aspect of the disclosure. The clip attach frame 400 includes a frame 410 and first clips 160_1 connected to the frame 410 by bars 420. The clip attach frame 400 is part of a clip attach reel, which extends from left to right in FIG. 4 and includes repeating clip attach frames 400 as shown in FIG. 4.

According to the first aspect of the disclosure, a first clip attach frame 400 for providing first clips 160_1 for a plurality of semiconductor packages 110 and a second clip attach frame (which is identical to the clip attach frame 400 shown) for providing second clips 160_2 may be used for clip attach to a plurality of semiconductor packages 100. That is, one clip attach frame 400 serves to provide the drain clips for a plurality of semiconductor packages 100 and another clip attach frame 400 (which is identical to clip attach frame 400) serves to provide the source clips for the semiconductor package 100.

The first clips 160_1 (e.g. drain clips) and the second clips 160_2 (e.g. source clips) are placed in subsequent pick-and-place operations per semiconductor package. However, cost reduction is achieved by the measure of using identically shaped clip attachment frames 400 for first clip and second clip attach.

In other words, two identically-shaped clip attachment reels each containing a sequence of clip attach frames 400 are used for applying the drain clip and the source clip per semiconductor package 100 in a sequential manner. In contrast to conventional clip attachment, these two clip reels (drain clip reel and source clip reel) are no longer shaped differently.

FIG. 5 illustrates a clip attach frame 500 according to the second aspect of the disclosure. The clip attach frame 500 is similar to the clip attach frame 400, and reference is made to the above description to avoid reiteration. However, clip attach frame 500 distinguishes from the clip attach frame 400 in that the first clip 160_1 and the second clip 160_2 are implemented in the same frame 510. More specifically, the clip attach frame 500 includes a frame 510 and first clips 160_1 and second clips 160_2 connected to the frame 510 by bars 520.

Only one clip attachment process is required to attach the first clip 160_1 and the second clip 160_2 (which can be of identical shape but can also be of different shape) together on the transistor chip 120 of each semiconductor package 200. Thus, cost reduction is achieved by the measure of needing only one clip attachment process for attaching simultaneously the first clip 160_1 and second clip 160_2. In this case, the clip attach reel, which extends from left to right in FIG. 5 and includes repeating clip attach frames 500, includes both clips 160_1 and 160_2. Only a single clip attach reel is needed for providing the first clip 160_1 and the second clip 160_2 for one or a plurality of semiconductor packages 200.

FIGS. 6A and 6B schematically illustrate conventional chip packages 600_1, 600_2, respectively. With regard to the first aspect of the disclosure, in FIG. 6A the first clip 160_1′ and the second clip 160_2′ are of different shape. Therefore, two clip attachment frames 400 (clip attach reels) of different designs would be needed to apply the (differently shaped) first and second clips 160_1′, 160_2′.

With regard to the second aspect of the disclosure, FIG. 6B illustrates that the narrow gap (of width W) between the first and second load electrodes 122_1, 122_2 prevents the first clip 160_1′ and the second clip 160_2′ to be fitted within the same clip attach frame 500 (clip attach reel) compare with FIG. 5. This is not possible since the SOH is large and thus the length needed for in-frame clip bending (i.e. for bending down the end of the clip 160_1′ to create the vertical clip portion 160_1V, which needs to be of similar length than SOH) is longer than the width W of the gap between the first and second load electrodes 122_1, 122_2 (i.e., SOH>W). Therefore, conventional first and second clips 160_1′, 160_2′ without the stepped section ST according to the second aspect of the disclosure need to be supplied in two separate clip attach frames (clip reels) and need to be placed by separate pick-and-place attachment processes.

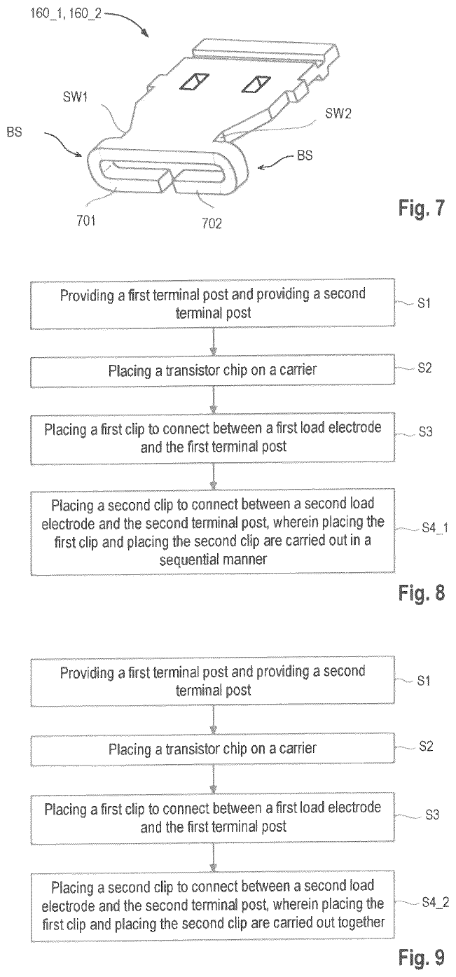

Referring to FIG. 7, in some examples, the vertical clip portion 160_1V of the first clip 160_1 and/or the vertical clip portion 160_2V of the second clip 160_2 may include or be made of one or more bending sections BS. The bending sections may be U-shaped. U-shaped bending section(s) BS allow(s) to provide large contact area(s) between the first clip 160_1 and the first load electrode 122_1 and/or between the second clip 160_2 and the second terminal post 140_2.

Each bending section BS may include or be formed of an integral contact element 701, 702 which projects from a lateral side wall SW1, SW2 of the first clip 160_1 and/or the second clip 160_2. The side wall SW1 is arranged opposite the first side wall SW2. The contact element 701, 702 is bent downwards in a direction towards the transistor chip 120 or the carrier 110 to electrically contact the first load electrode 122_1 or the first terminal post 140_2. A bending axis is in a longitudinal direction of the first clip 160_1 and/or the second clip 160_2. The contact elements 701, 702 forming the U-shaped bending sections BS may each be bent by more than 90° and, in particular, by about 180°, for example. The contact elements 701, 702 at both sides of the respective clip 160_1, 160_2 facilitate the clip attach process and improve mechanical stability of the respective clip 160_1, 160_2 mounted on the transistor chip 120.

Due to the U-shaped bending section(s) BS, a contact surface of the contact element 701, 702 which faces the transistor chip 120 (first clip 160_1) or the carrier 110 (second clip 160_2) is a bent portion of an upper surface of the respective clip 160_1 or 160_2 which faces away from the transistor chip 120 or the carrier 110.

The U-shaped bending sections BS make it possible to form the vertical clip portion 160_1V without sharp cutting edges that could come into contact with the sensitive surface of the first load electrodes 122_1. Therefore, there is less risk of damage to the transistor chip 120 during the process of clip placement. In contrast, if the vertical clip portion 160_1V is formed by bending around a transverse axis of the respective clip 160_1, sharp cutting edges at the ends of the vertical clip portion 160_1V may damage the first load electrode 122_1.

Further, it has been verified by simulations that longitudinal-axis bending of contact elements 701, 702 provides electrical package resistances which are comparable with the electrical package resistances obtained with transverse-axis bending (e.g., FIGS. 1 and 2) of the clips 160_1, 160_2. These package resistances are significantly lower than any package resistances which can be obtained by using bond wires instead of clips.

In addition, as the bending axis is in the longitudinal direction of the first clip 160_1 or the second clip 160_2 rather than in the transverse direction, the bending process(es) carried out at the first clip 160_1 do not interfere with the position of the second clip 160_2 if, e.g., arranged in the same clip reel. Therefore, both clips 160_1, 160_2 can be integrated on one and the same clip attach frame 500 as shown in FIG. 7.

In other words, in contrast to the situation when using a bending axis in transverse direction, there is always enough space and material to complete both clips 160_1, 160_2 in the same clip attach frame. This is due to the fact that the dimensional limitation as illustrated in FIG. 6B exists in the longitudinal direction, while the bending is relocated in the transverse direction when using clips 160_1, 160_2 with he bending sections BS.

Referring to FIG. 8, a method of manufacturing a semiconductor package 100 according to the first aspect of the disclosure includes, at S1, providing a first terminal post and providing a second terminal post.

At S2, a transistor chip is placed on a carrier.

At S3, the first clip is placed to connect between the first load electrode and the first terminal post.

At S4_1, the second clip is placed to connect between the second load electrode and the second terminal post. Here, placing the first clip (at S3) and placing the second clip (at S4_1) are carried out in a sequential manner, for example.

Referring to FIG. 9, a method of manufacturing a semiconductor package 200 in accordance with the second aspect of the disclosure may include the same stages S1 to S3 as described above. Further, at S4_2, the second clip is placed to connect between the second load electrode and the second terminal post, wherein placing the first clip (at S3) and placing the second clip (at S4_2) are carried out together, for example. Thus, one pick-and-place operation per semiconductor package 200 may be sufficient.

This method of fabrication can also be used for the first aspect of the disclosure if the vertical clip portions 160_1V, 160_2V include bending sections BS allowing to integrate both clips 160_1, 160_2 within the same clip attach frame 500.

The following examples pertain to further aspects of the disclosure:

Example 1 is a semiconductor package comprising a transistor chip having a first side and a second side opposite the first side. The transistor chip comprises a first load electrode and a second load electrode on the first side. The package comprises a carrier facing the second side of the transistor chip, a first terminal post arranged laterally beside the transistor chip and a second terminal post arranged laterally beside the transistor chip on an opposite side of the transistor chip. The second terminal post is a part of the carrier or physically connects to the carrier. A first clip connects the first load electrode to the first terminal post. A second clip connects the second load electrode to the second terminal post. An upper surface of the first terminal post and an upper surface of the second terminal post are arranged at different levels of height measured from an upper surface of the carrier. The first clip and the second clip are of same shape.

In Example 2, the subject matter of Example 1 can optionally include wherein the first clip and the second clip comprise a vertical clip portion extending in a vertical direction and a horizontal clip portion extending in a horizontal direction, and wherein the horizontal clip portion of the first clip is attached to the first terminal post and the vertical clip portion of the first clip is attached to the first load electrode.

In Example 3, the subject matter of Example 2 can optionally include wherein the horizontal clip portion of the second clip is attached to the second load electrode and the vertical clip portion of the second clip is attached to the second terminal post.

In Example 4, the subject matter of Example 3 or 4 can optionally include wherein the horizontal clip portion has an end section comprising a stepped abutment surface comprising a lower abutment surface portion and a higher abutment surface portion.

In Example 5, the subject matter of Example 4 can optionally include wherein the higher abutment surface portion of the first clip is placed on the first terminal post and the lower abutment surface potion of the second clip is placed on the second load electrode.

In Example 6, the subject matter of any of the preceding Examples can optionally include wherein the first clip and the second clip are same in 3D dimensions.

In Example 7, the subject matter of any of the preceding Examples can optionally include wherein the first load electrode and the second load electrode are laterally spaced apart by a gap of width W, a free height of the vertical clip portion is SOH, and W<SOH.

In Example 8, the subject matter of any of the preceding Examples can optionally include wherein the carrier is a part of a leadframe.

In Example 9, the subject matter of any of the preceding Examples can optionally include wherein the package is a leaded package, a lead extends out from a sidewall of the package to form a first terminal of the package and the first terminal post is a lead posts.

In Example 10, the subject matter of any of the preceding Examples can optionally include wherein the transistor chip is a lateral power chip, in particular a GaN chip.

In Example 11, the subject matter of any of the preceding Examples can optionally include wherein the first load electrode and the second load electrode are drain and source electrodes, respectively.

In Example 12, the subject matter of any of the preceding Examples can optionally include wherein the first clip and the second clip each comprises a first contact element which projects from a first side wall of the first clip or the second clip, respectively, and is bent downwards, a bending axis being in a longitudinal direction of the first clip or the second clip.

In Example 13, the subject matter of Example 12 can optionally include wherein the first clip and the second clip each comprises a second contact element which projects from a second side wall of the first clip or the second clip, respectively, and is bent downwards, a bending axis being in a longitudinal direction of the first clip or the second clip, wherein the second side wall is arranged opposite the first side wall.

In Example 14, the subject matter of Example 12 or 13 can optionally include wherein the first contact element and/or the second contact element is U-shaped.

Example 15 is a method of manufacturing the semiconductor package according to any of the preceding Examples. The method comprises providing the first terminal post and providing the second terminal post. The method further comprises placing the transistor chip on the carrier. The first clip is placed to connect between the first load electrode and the first terminal post. The second clip is placed to connect between the second load electrode and the second terminal post.

In Example 16, the subject matter of Example 15 can optionally include wherein placing the first clip and placing the second clip are carried out in a sequential manner.

Example 17 is a semiconductor package comprising a transistor chip having a first side and a second side opposite the first side. The transistor chip comprises a first load electrode and a second load electrode on the first side. The package comprises a carrier facing the second side of the transistor chip, a first terminal post arranged laterally beside the transistor chip and a second terminal post arranged laterally beside the transistor chip on an opposite side of the transistor chip. The second terminal post is a part of the carrier or physically connects to the carrier. A first clip connects the first load electrode to the first terminal post. A second clip connects the second load electrode to the second terminal post. An upper surface of the first terminal post and an upper surface of the second terminal post are arranged at different levels of height measured from an upper surface of the carrier. The first clip comprises a vertical clip portion extending in a vertical direction and a horizontal clip portion extending in a horizontal direction, the horizontal clip portion having a first horizontal section and a second horizontal section, the first horizontal section and the second horizontal section are connected by a vertically stepped section.

In Example 18, the subject matter of Example 17 can optionally include wherein the first load electrode and the second load electrode are laterally spaced apart by a gap of width W, a free height of the vertical clip portion of the first clip is SOH, and W>SOH.

In Example 19, the subject matter of Example 17 or 18 can optionally include wherein the horizontal clip portion of the first clip is attached to the first terminal post and the vertical clip portion of the first clip is attached to the first load electrode.

In Example 20, the subject matter of any of Examples 17 to 19 can optionally include wherein the second clip comprises a vertical clip portion extending in a vertical direction and a horizontal clip portion extending in a horizontal direction.

In Example 21, the subject matter of Example 20 can optionally include wherein the horizontal clip portion of the second clip is attached to the second load electrode and the vertical clip portion of the second clip is attached to the second terminal post.

In Example 22, the subject matter of any of Examples 17 to 21 can optionally include wherein the first clip and the second clip are of same shape.

In Example 23, the subject matter of any of Examples 17 to 22 can optionally include wherein the second terminal post is part of the carrier.

Example 24 is a method of manufacturing the semiconductor package according to any of the Examples 17 to 23. The method comprises providing the first terminal post and providing the second terminal post. The method further includes placing the transistor chip on the carrier. The first clip is placed to connect between the first load electrode and the first terminal post. The second clip is placed to connect between the second load electrode and the second terminal post.

In Example 25, the subject matter of Example 24 can optionally include wherein placing the first clip and placing the second clip are carried out together.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A semiconductor package comprising:
a transistor chip having a first side and a second side opposite the first side, the transistor chip comprises a first load electrode and a second load electrode on the first side;
a carrier facing the second side of the transistor chip,
a first terminal post arranged laterally beside the transistor chip;
a second terminal post arranged laterally beside the transistor chip on an opposite side of the transistor chip, wherein the second terminal post is a part of the carrier or physically connects to the carrier;
a first clip connecting the first load electrode to the first terminal post;
a second clip connecting the second load electrode to the second terminal post; wherein
an upper surface of the first terminal post and an upper surface of the second terminal post are arranged at different levels of height measured from an upper surface of the carrier, and
the first clip and the second clip are of same shape.

2. The semiconductor package of claim 1, wherein the first clip and the second clip comprise a vertical clip portion extending in a vertical direction and a horizontal clip portion extending in a horizontal direction, and wherein the horizontal clip portion of the first clip is attached to the first terminal post and the vertical clip portion of the first clip is attached to the first load electrode.

3. The semiconductor package of claim 2, wherein the horizontal clip portion of the second clip is attached to the second load electrode and the vertical clip portion of the second clip is attached to the second terminal post.

4. The semiconductor package of claim 2, wherein the horizontal clip portion has an end section comprising a stepped abutment surface comprising a lower abutment surface portion and a higher abutment surface portion.

5. The semiconductor package of claim 4, wherein the higher abutment surface portion of the first clip is placed on the first terminal post and the lower abutment surface portion of the second clip is placed on the second load electrode.

6. The semiconductor package of claim 1, wherein the first clip and the second clip are same in 3D dimensions.

7. The semiconductor package of claim 2, wherein the first load electrode and the second load electrode are laterally spaced apart by a gap of width W, a free height of the vertical clip portion is SOH, and W<SOH.

8. The semiconductor package of claim 1, wherein the carrier is a part of a leadframe.

9. The semiconductor package of claim 1, wherein the package is a leaded package, a lead extends out from a sidewall of the package to form a first terminal of the package and the first terminal post is a lead posts.

10. The semiconductor package of claim 1, wherein the transistor chip is a lateral power chip, in particular a GaN chip.

11. The semiconductor package of claim 1, wherein the first load electrode and the second load electrode are drain and source electrodes, respectively.

12. The semiconductor package of claim 1, wherein the first clip and the second clip each comprises a first contact element which projects from a first side wall of the first clip or the second clip, respectively, and is bent downwards, a bending axis being in a longitudinal direction of the first clip or the second clip.

13. The semiconductor package of claim 12, wherein the first clip and the second clip each comprises a second contact element which projects from a second side wall of the first clip or the second clip, respectively, and is bent downwards, a bending axis being in a longitudinal direction of the first clip or the second clip, wherein the second side wall is arranged opposite the first side wall.

14. The semiconductor package of claim 12, wherein the first contact element and/or the second contact element is U-shaped.

15. A method of manufacturing a semiconductor package comprising a transistor chip having a first side and a second side opposite the first side, the transistor chip comprises a first load electrode and a second load electrode on the first side; a carrier facing the second side of the transistor chip,
a first terminal post arranged laterally beside the transistor chip; a second terminal post arranged laterally beside the transistor chip on an opposite side of the transistor chip, wherein the second terminal post is a part of the carrier or physically connects to the carrier; a first clip connecting the first load electrode to the first terminal post; a second clip connecting the second load electrode to the second terminal post; wherein an upper surface of the first terminal post and an upper surface of the second terminal post are arranged at different levels of height measured from an upper surface of the carrier, and the first clip and the second clip are of same shape, the method comprising:
providing the first terminal post and providing the second terminal post;
placing the transistor chip on the carrier;
placing the first clip to connect between the first load electrode and the first terminal post; and
placing the second clip to connect between the second load electrode and the second terminal post.

16. A semiconductor package comprising:
a transistor chip having a first side and a second side opposite the first side, the transistor chip comprises a first load electrode and a second load electrode on the first side;
a carrier facing the second side of the transistor chip,
a first terminal post arranged laterally beside the transistor chip;
a second terminal post arranged laterally beside the transistor chip on an opposite side of the transistor chip, wherein the second terminal post is a part of the carrier or physically connects to the carrier;
a first clip connecting the first load electrode to the first terminal post;
a second clip connecting the second load electrode to the second terminal post; wherein
an upper surface of the first terminal post and an upper surface of the second terminal post are arranged at different levels of height measured from an upper surface of the carrier, and wherein
the first clip comprises a vertical clip portion extending in a vertical direction and a horizontal clip portion extending in a horizontal direction, the horizontal clip portion of the first clip having a first horizontal section and a second horizontal section, the first horizontal section and the second horizontal section are connected by a vertically stepped section.

17. The semiconductor package of claim 16, wherein the first load electrode and the second load electrode are laterally spaced apart by a gap of width W, a free height of the vertical clip portion of the first clip is SOH, and W>SOH.

18. The semiconductor package of claim 16, wherein the horizontal clip portion of the first clip is attached to the first terminal post and the vertical clip portion of the first clip is attached to the first load electrode.

19. The semiconductor package of claim 16, wherein the second clip comprises a vertical clip portion extending in a vertical direction and a horizontal clip portion extending in a horizontal direction, and wherein the horizontal clip portion of the second clip is attached to the second load electrode and the vertical clip portion of the second clip is attached to the second terminal post.

20. The semiconductor package of claim 16, wherein the first clip and the second clip are of same shape.
